(19) United States
(12) Patent Application Publication
(10) Pub. No.: US 2007/0009067 A1
(43) Pub. Date: Jan. 11, 2007

(54) Methods and apparatus for radio frequency interference reduction

(76) Inventor: Gerald Paul Michalak, Cary, NC (US)

Correspondence Address: QUALCOMM INCORPORATED, 5775 MOREHOUSE DR., SAN DIEGO, CA, 92121, US

(21) Appl. No.: 11/177,740

(22) Filed: Jul. 8, 2005

(51) Int. Cl. H03D 1/04

(52) U.S. Cl. 375/346

(57) ABSTRACT

Techniques for reducing interference on radio frequencies due to processor frequencies which control a processor in wireless device are disclosed. A method for reducing interference on radio frequencies includes the steps of determining at least one radio frequency used in the wireless device and assigning an interference factor to a potential processor frequency corresponding to at least one radio frequency used in the wireless device. The method further includes the step of selecting a first processor frequency other than the potential processor frequency to avoid interference with the at least one radio frequency.

### BACKGROUND OF THE INVENTION

1. Field of the Invention

The present invention relates generally to reducing processor generated interference with radio frequencies used in a wireless device, and, more particularly, to advantageous techniques for selecting a processor frequency for operating a processor or other peripherals based on the radio frequencies presently utilized or planned to be used by the wireless device.

2. Relevant Background

Common radio frequency bands for today's wireless communication systems range from around 400 MHz to over 2.4 GHz. Within this range, frequency sub-bands are defined for wireless communication such as the cellular band, the global positioning system (GPS) band, the personal communication service (PCS) band, the international mobile telecommunication (IMT) band, and the general use frequency band which includes the Bluetooth® communication protocol. A wireless device typically has radio circuits which communicate in one or more of these radio frequency bands.

The speed at which microprocessors operate in wireless devices continues to increase. It is expected that this trend of increasing processor speed will continue in order to satisfy the demand for additional functions on the wireless device, such as television applications, high intensity video gaming applications, or the like.

As the speed of microprocessors increases, power consumption on the wireless device increases as well. In order to address power consumption issues, some conventional processors have been developed that employ dynamic frequency scaling which means that the processor can adjust its clock rate higher or lower over. This adjustment is commonly performed in response to changes in the of work load of the processor. With a high work load, the processor runs at the higher clock rate to meet the needs of the high work load. However, the power consumption of the processor running at the higher clock rate is higher than the power consumption when the processor is running at a lower clock rate to handle a lighter work load.

Classic interference reduction techniques such as filtering, static processor clock selection and physical shielding are commonly used to reduce processor interference with radio frequencies by the device. However, these techniques are static in nature because they require careful frequency planning at design or provisioning time to preclude use of operating a processor at radio frequencies. Accordingly there is a need in the art for flexible techniques to allow adaptive energy consumption while still allowing a wide range of processor frequencies to be utilized without undue interference of radio frequencies.

### SUMMARY OF THE DISCLOSURE

As the speed of microprocessors increase and those increased speeds enter the frequency range of the radio frequency band, running microprocessors at speeds within the radio frequency band may cause interference with a wireless device's radio circuits. Furthermore, the harmonic frequencies resulting from microprocessors running at speeds within the radio frequency band may also cause interference with the radio circuits.

Moreover, embodiments of the present invention recognize a need for methods, apparatus, and computer readable medium for dynamically determining processor frequencies to operate a processor or other peripheral device in a wireless device to reduce interference on radio frequencies used by the wireless device. The interference to be reduced may include interference signals caused by the operating speed of the processor, clock signals driving peripheral devices, and the harmonic frequencies generated from signals generated at a processor frequency. By utilizing knowledge of the radio frequencies in use or those frequencies that might be used in dynamically determining a processor frequency for a processor or other peripheral, an embodiment of the present invention controls processor operation so that it operates at frequencies and generates harmonics within the radio frequency range during a time when those corresponding radio frequencies are not being used by a radio in the wireless device. This runtime interference avoidance technique provides frequency scaling processors more freedom in the selection of operating frequencies thereby allowing better optimization of throughput versus energy consumption.

To such ends, an embodiment of the present invention includes a method having the steps of determining at least one radio frequency used in the wireless device and assigning an interference factor to a potential processor frequency corresponding to at least one radio frequency used in the wireless device. The method further includes the step of selecting a first processor frequency other than the potential processor frequency to avoid interference with the at least one radio frequency.

A more complete understanding of the present invention, as well as further features and advantages of the invention, will be apparent from the following Detailed Description and the accompanying drawings.

### BRIEF DESCRIPTION OF THE DRAWINGS

FIG. 1 is a graphic illustration of an exemplary wireless communication system in which an embodiment of the invention may be employed.

FIG. 2 is a block diagram of a wireless device in accordance with an embodiment of the invention.

FIG. 3 is a graphic illustration of an exemplary radio frequency table in accordance with the embodiment of the invention.

FIG. 4 is a graphic illustration of an exemplary allowance table of FIG. 2 in accordance with the embodiment of the invention.

FIG. 5 is a graphic illustration of an exemplary use case of selecting a processor speed to reduce interference with used radio frequencies in accordance with the embodiment of the invention.

FIG. 6 is a spectral density graph which illustrates slewing the operating frequency of the processor of FIG. 2 from the current operating frequency to a selected operating frequency in accordance with the embodiment of the invention.

FIG. 7 is a flow chart illustrating a method for reducing interference with used radio frequencies by selecting a processor speed or clock signal to avoid used radio frequencies in accordance with the embodiment of the invention.

### DETAILED DESCRIPTION

The present invention will now be described more fully with reference to the accompanying drawings, in which several embodiments of the invention are shown. This invention may, however, be embodied in various forms and should not be construed as limited to the embodiments set forth herein. Rather, these embodiments are provided so that this disclosure will be thorough and complete, and will fully convey the scope of the invention to those skilled in the art.

It will be appreciated that the present invention may be embodied as methods, systems, or computer program products. Accordingly, the present invention may take the form of a hardware embodiment, a software embodiment or an embodiment combining software and hardware aspects. Furthermore, the present invention may take the form of a computer program product on a computer-usable storage medium having computer-usable program code embodied in the medium. Any suitable computer readable medium may be utilized including hard disks, CD-ROMs, optical storage devices, flash memories, or magnetic storage devices.

Computer program code which may be compiled, assembled, predecoded after compiling or assembly, or the like in accordance with the teachings of the invention may be initially written in a programming language such as C, C++, native Assembler, JAVA®, Smalltalk, JavaScript®, Visual Basic®, TSQL, Perl, or in various other programming languages. Program code or computer readable medium refers to machine language code such as object code whose format is understandable by a processor. Software embodiments of the invention do not depend upon their implementation with a particular programming language. When program code is executed, a new task which defines the operating environment for program code is created.

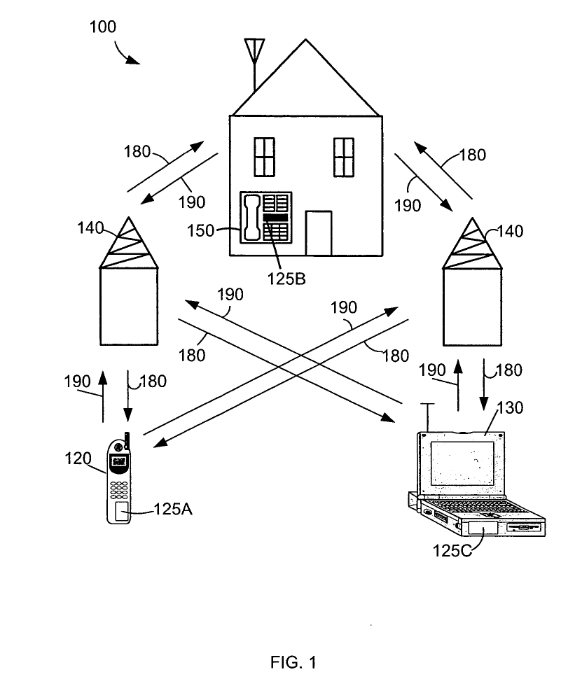

FIG. 1 shows an exemplary wireless communication system 100 in which an embodiment of the invention may be employed. For purposes of illustration, FIG. 1 shows three remote units 120, 130, and 150 and two base stations 140. It will be recognized that typical wireless communication systems may have many more remote units and base stations. Remote units 120, 130, and 150 include hardware components, software components, or both as represented by components 125A, 125B, and 125C, respectively, which are embodiments of the invention as discussed further below. FIG. 1 shows forward link signals 180 from the base stations 140 and the remote units 12, 13, and 15 and reverse link signals 190 from the remote units 12, 13, and 15 to base stations 140.

In FIG. 1, remote unit 120 is shown as a mobile telephone, remote unit 130 is shown as a portable computer, and remote unit 150 is shown as a fixed location remote unit in a wireless local loop system. For example, the remote units may be cell phones, handheld personal communication systems (PCS) units, portable data units such as personal data assistants, or fixed location data units such as meter reading equipment. Although FIG. 1 illustrates remote units according to the teachings of the invention, the invention is not limited to these exemplary illustrated units. The invention may be suitably employed in any device which includes both radio circuitry and a functional baseband processing component.

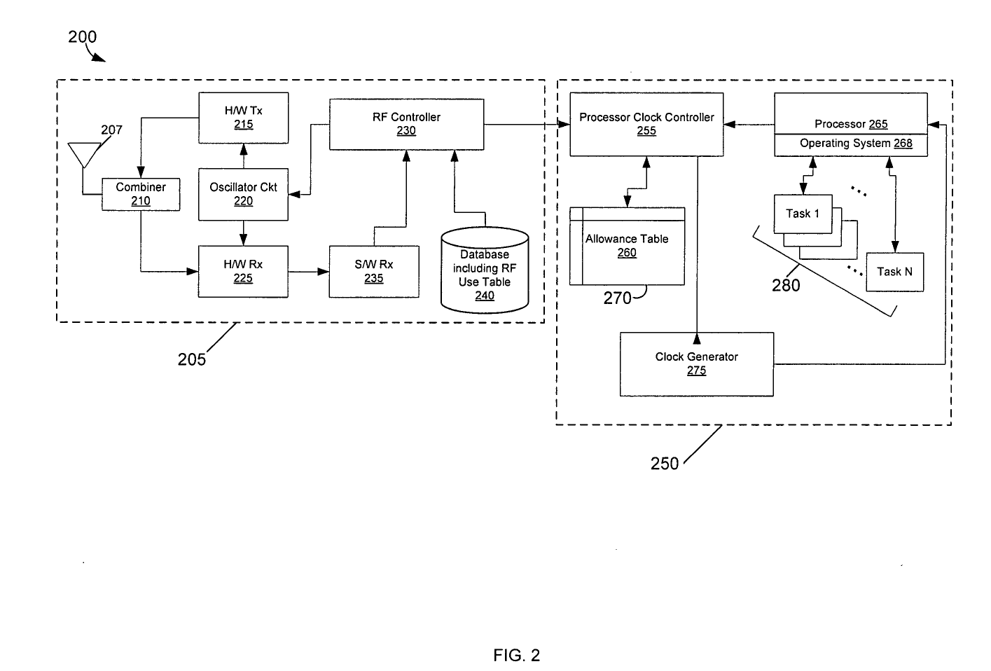

FIG. 2 is a block diagram of a wireless device 200 in accordance with an embodiment of the invention. The wireless device 200 may be used within a wide variety of components, such as components 125A, 125B, and 125C of FIG. 1. The wireless device 200 comprises a radio 205 and a baseband processing component 250. In short, the radio 205 receives and transmits information over various radio frequencies. These radio frequencies may hop and change from time to time. The radio 205 includes a hardware transmission circuit 215, a hardware receiver circuit 225, a software receiver module 235, an oscillator circuit 220, a combiner 210, a radio frequency controller 230, and memory 240 which contains a database of provisioned frequencies over which the radio 205 may communicate. Memory 240 may also include a radio frequency table indicating the frequencies currently being used or which will be used in the future.

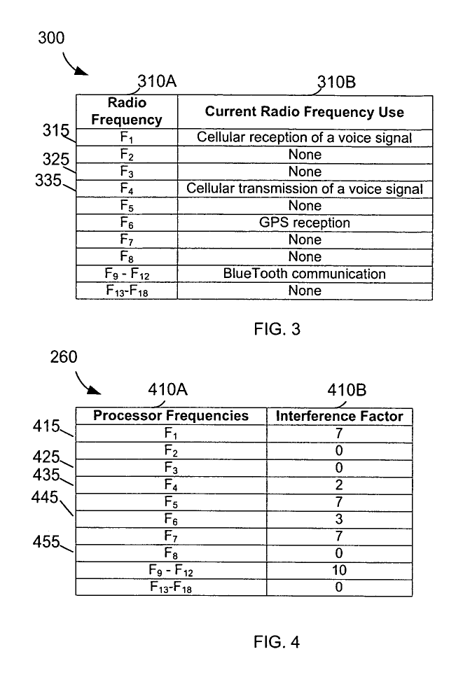

The radio frequency table will be discussed in further detail in connection with the discussion of FIG. 3 below. The radio frequency controller 230 couples to the baseband processing component 250, the oscillator circuit 220, the software receiver module 235, and memory 240. The oscillator circuit 220 further couples to the hardware transmission circuit 215 and the hardware receiver circuit 225. The hardware transmission circuit 215 further couples to the combiner 210. The hardware receiver circuit 225 further couples to the combiner 210 and the software receiver module 235.

During operation, the radio frequency controller 230 retrieves a transmitting frequency and a receiving frequency from memory 240. The memory 240 may also contain allowable frequencies which have been dynamically determined based on the available frequencies for a region in which the wireless device 200 operates. For example, a wireless device having a global position system may sense its region of operation and retrieve a transmitting and receiving frequency from the memory 240 which corresponds to the sensed region of operation. The radio frequency controller 230 communicates both the transmitting and receiving frequencies to the oscillator circuit 220. The radio frequency controller 230 may suitably be implemented in appropriate code according to the teachings of the invention running a microprocessor.

The oscillator circuit 220 generates first and second clock signals corresponding to the retrieved transmitting and receiving frequency, respectively. The oscillator circuit 220 sends the first clock signal to the hardware transmission circuit 215 and the second clock signal to the hardware receiver circuit 225. In general, clock signals are typically square waves. Consequently, the first and second clock signals are susceptible to interference with other signals having the same frequency and signals having frequencies equal to their odd harmonics.

The hardware transmission circuit 215 may suitably be a known radio frequency transmission circuit which steps up the strength of a carrier signal at the frequency defined by the first clock signal. The carrier signal carries baseband information produced by the wireless device 200 to define an outgoing radio frequency signal. For ease of illustration, the baseband connections to the hardware transmission circuit 215 are not shown. The combiner 210 accepts the outgoing radio frequency signal from the hardware transmission circuit 215 and couples it to antenna 207.

When receiving a signal through antenna 207, the combiner 210 couples the received signal to the hardware reception circuit 225. The hardware reception circuit 225 removes the carrier signal from the received signal to output the baseband signal to the software receiver module 235. The hardware reception circuit 225 may suitably be a high gain circuit for receiving a low power incoming signal and stepping up the strength of the baseband signal. The software receiver module 235 decodes the baseband signal to provide the information content to the radio frequency controller 230 for subsequent consumption. Furthermore, the software receiver module 235 may optionally analyze the decoded information to determine whether the transmitting or receiving carrier frequencies will change in the near future as a result of communicating with an external device such as a base station or the like. For example, a base station may communicate one or more supported frequencies over which the wireless device may choose to communicate. The software receiver module 235, in this example, determines those suggested frequencies and communicates those suggested frequencies to the radio frequency controller 230. The radio frequency controller 230 may write those suggested frequencies into a radio frequency table in memory 240, may utilize those suggested frequencies by communicating them to the radio oscillator circuit 220, or both. It should be noted that the radio frequencies used by a wireless device may hop from one frequency to another with regularity.

The baseband processing component 250 includes a processor clock controller 255, a clock generator 275, an allowance table 260 stored in memory 270, a processor 265, and an operating system 268 which provides a platform upon which software tasks 280 may run. The term “operating system” as used herein may include known operating systems, kernels, simple schedulers, and the like. The processor clock controller 255 couples to the radio frequency controller 230, the allowance table 260, the clock generator 275 and the processor 265. The clock generator 275 further couples to processor 265. Software tasks 280 couple to the operating system 268.

The processor clock controller 255 is typically a software component that accepts status information from radio frequency controller 230. The status information may include current frequencies being utilized by the radio 205, candidate frequencies which may be utilized by the radio 205, a particular use by the radio 205 for these candidate frequencies, and the bandwidth associated with each of these reported frequencies. The status information may optionally include other information such as current signal strength, signal-to-noise ratio (SNR) of the candidate frequencies, and the like. The processor clock controller 255 utilizes the status information and the allowance table 260 to determine at what frequency processor 265 will operate. The allowance table 260 includes potential processor frequencies or clock speeds at which processor 265 or other peripheral device may operate. The processor clock controller 255 modifies the potential processor frequencies if the frequencies in the status information correspond to frequencies in the allowance table 260. The processor clock controller 255 may also modify the potential processor frequencies further if the harmonics of the frequencies in the status information correspond to frequencies in the allowance table 260. A more detailed description of the allowance table 260 and these modifications are provided in connection with the discussion of FIG. 4.

The processor clock controller 255 from time to time evaluates the work load offered by software tasks 280 to determine a processor frequency at which to operate processor 265 to meet the needs of the offered work load while minimizing battery consumption. For example, this evaluation may occur at 50 millisecond intervals. The work load on the processor 265 is dependent on the number of tasks in software tasks 280 and the amount of instructions which are ready to execute in each task. A software task may include, for example, displaying video on a screen, rendering video game graphics, or the like. Increasing the operating speed of processor 265, increases the speed of execution of software tasks 280 at the expense of higher power consumption.

This evaluation also includes selecting a processor frequency from the allowance table 260 to reduce interference effects potentially caused by operating processor 265 at a selected frequency. In this way, the processor clock controller 255 selects a frequency at which processor 265 will operate based on both radio frequencies used to reduce interference and offered load information to balance power consumption. The processor clock controller 255 communicates this selected frequency to the clock generator 275. The clock generator 275 generates a clock signal based on the selected frequency and drives processor 265 or other device peripherals with the generated clock signal. It is noted that each peripheral may or may not have its own frequency scaling processor. Furthermore, each peripheral may be driven by a clock signal having a different frequency.

Alternatively, the processor clock controller 255 may provide entries of the allowance table 260 as input to a known dynamic frequency selection technique which selects a frequency based only on work load. In this alternative, the processor clock controller 255 provides potential processor frequencies which have already excluded used radio frequencies without having to make a selection.

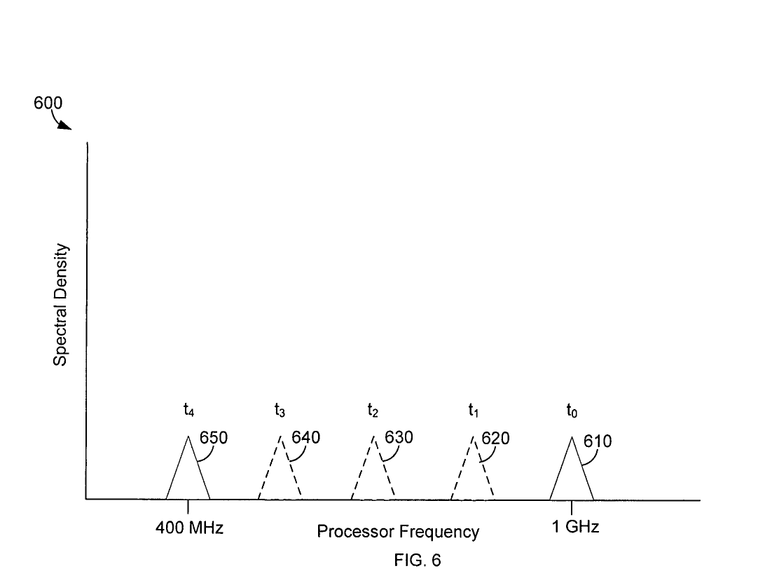

Since processor frequency selection is dynamic and is made from time to time, the processor 265 may have to change from one operating frequency to a newly selected second operating frequency. One approach for moving from one operating frequency to another includes turning off the current clock rate followed by turning on the selected clock rate. A second approach includes slewing the clock rate in incremental steps from the first clock rate to the selected clock rate. A more detailed description of slewing the clock rate to reduce interference with used radio frequencies is provided in connection with the discussion of FIG. 6.

It is noted that the radio frequency controller 230 and the processor clock controller 255 may be embodied in code and execute on the same processor 265 or different processors. In such a software embodiment, communications between the radio frequency controller 230 and the processor clock control 255 may include many known software techniques such as remote procedure call (RPC), inter-task message passing, common variable access, or the like. Alternatively, the radio frequency controller 230 and the processor clock controller 255 may be embodied in a hardware circuit or firmware. In this alternative embodiment, communications between the radio frequency controller 230 and the processor clock control 255 may include many known hardware or firmware techniques including setting and reading a status register or registers, passing a stream of serial information, or the like.

FIG. 3 shows an exemplary radio frequency table 300 in accordance with an embodiment of the invention. The radio frequency table 300 may be stored in database 240 or any other memory device accessible by the radio frequency controller 230. As shown, the radio frequency table 300 includes columns 310A and 310B. Column 310A contains a radio frequency or a range of radio frequencies at which a radio such as radio 205 may communicate. Column 310B indicates a particular use for the corresponding frequency. For example, referring to row 315, F₁ is currently being used or will be used in the near term for cellular reception of a voice signal. If the entry is labeled “None” as in row 325, for example, the corresponding frequency is not being used by radio 205. As different radio frequencies are used for different purposes, the radio frequency controller 230 modifies the radio frequency table 300, stores the modified radio frequency table 300, and communicates the used frequencies and their particular use through a status information message to the processor clock controller 255. FIG. 3 will be described in further detail below in connection with FIG. 4.

FIG. 4 shows an exemplary allowance table 260 in accordance with an embodiment of the invention. The allowance table 260 includes columns 410A and 410B. Column 410A contains potential processor frequencies which can be used with processor 265 or other peripheral devices. Column 410B contains an interference factor which may be a weighted value between 0 and 10. A value of 0 means the corresponding processor frequency is available for use. A value of 0 may also indicate a potential radio frequency which does not correspond to a used radio frequency, and, thus, the potential radio frequency is unassigned. A value of 10 means the corresponding processor frequency is not available for use. Any value between 1 and 9 indicates that the corresponding processor frequency may or may not be available use. In the described embodiment where interference factor is between 1 and 9, the interference factor is compared to a system tolerance level. An example of selecting a processor frequency while considering the system tolerance level will be described below.

Two main phases of operation, a maintenance phase and a selection phase, involve the allowance table 260. During the maintenance phase, the processor clock controller 255 receives information corresponding to the radio frequency table 300. Alternatively to receiving an entire table's worth of information, the processor clock controller 255 may receive only the used frequencies and their associated uses. The processor clock controller 255 transforms the used frequencies using bandwidth information and harmonic multipliers to determine corresponding processor frequencies in column 410A of allowance table 260. The bandwidth information may be passed as separate parameters in a status information message from the radio frequency controller 230. Harmonic multipliers may be determined by the particular use of a radio frequency or may be pre-defined. The processor clock controller 255 then assigns an interference factor associated with the determined frequencies based on the particular usages of the corresponding used radio frequencies.

For example, referring to row 315 of radio frequency table 300, frequency F₁ is currently being used for cellular reception of a voice signal. When the processor clock controller 255 analyzes F₁ and its corresponding use, the processor clock controller 255 determines, for example, that the 5^{th} and 7^{th} harmonics of F₁ should be considered. The processor clock controller 255 assigns a weighted interference factor of 7 to F₁, F₅, and F₇ as shown in allowance table 260. This weight factor is utilized during the selection phase described below. It should be noted that the processor clock controller 255 may assign weights to the harmonic frequencies F₅ and F₇ which are different from the weight assigned to F₁. Such a varying weight assignment is particularly useful when the impact of interference on a harmonic varies in level depending on the degree of the harmonic.

By way of another example, referring to row 335 of the radio frequency table 300, frequency F₄ is currently being used for cellular transmission of a voice signal. When the processor clock controller 255 analyzes F₄ and its corresponding use, the processor clock controller 255 assigns a weight factor of 2 to F₄ as shown in the allowance table. The lower weight indicates that depending on the strength of the transmission signal, some interference may be tolerated. For example, if the battery level of a wireless device is high and a strong cellular transmission signal is currently being produced, the likelihood of interference with the transmission signal is reduced. Thus, a lower weight factor is assigned.

Assignment of a weighted interference factor to a processor frequency may include many considerations including whether a corresponding radio frequency is sufficiently shielded by a particular hardware design, whether a harmonic of a corresponding radio frequency is sufficiently shielded by a particular hardware design, strength of a signal, a tolerance for noise of the signal, whether a digital signal is involved, quality of service requirements for the wireless device, and the like. If, for example, the strength of signal is considered, the stronger the strength of the used radio frequency, the lower an interference factor would be assigned to the corresponding processor frequency. If, for example, a digital signal is being communicated is considered, the effectiveness of error correction coding of the digital signal may be analyzed when assigning a weighted interference factor.

The described embodiment of the present invention allows selection of a processor frequency which corresponds to a radio frequency if there are other mechanisms in the wireless device that sufficiently protect that radio frequency from interference. Such leveraging of other techniques allows the embodiment of the invention to be advantageously flexible in not precluding frequencies unnecessarily.

During the selection phase, the processor clock controller 255 determines that a new processor frequency needs to be selected. This determination may be done from time to time or on a periodic basis such as every 50 milliseconds. In making the selection, the processor clock controller 255 considers the current offered work load and balances battery consumption for operating the processor 265 to meet the needs of the offered work load. In so doing, the processor clock controller 255 accesses a system tolerance level. The system tolerance level may suitably be a register or software variable which aggregates operating characteristics of the wireless device such as the current level of battery, work load, and the like. In deciding whether to select a frequency, the processor clock controller 255 compares an interference factor associated with a processor frequency in the allowance table 260 with the system tolerance level. If the interference factor is greater than the system tolerance level, the corresponding processor frequency is to be avoided. Otherwise, the corresponding frequency may be selected.

For example, if the processor 265 was operating at frequency F₈ and the processor clock controller 255 determines that the clock rate of processor 265 may be decreased because the desired work load is being met, the processor clock controller 255 would evaluate the interference factor of the next lower frequency, F₇, for example. In evaluating whether to select F₇, the processor clock controller 255 compares the interference factor 7 with the current system tolerance level. If the interference factor is greater than the current system tolerance level, F₇ would not be selected. Assuming that the current system tolerance level is 6, the processor clock controller 255 would then consider F₆ and find that the interference level associated with F₆ is less than the current system tolerance level. Thus, the processor clock controller 255 would select F₆.

Using this technique, when the system tolerance level is set to 0, in the extreme situation, only a radio frequency that has a 0 interference factor will be selected. This setting may occur when the battery level is high but the receiving signal strength of the radio is low. When the system tolerance level is set to 10, in the other extreme situation, any frequency may be selected. This setting may occur when the battery level is low and all signals used by the radio are running at a high power level to give preference to battery energy conservation.

It should be recognized that another embodiment of the invention may include an interference factor that contains a binary value. If the interference factor has one value, the processor clock controller 255 may select the corresponding processor frequency. If the interference factor has the other value, the processor clock controller 255 must not select the corresponding processor frequency. When an interference factor contains a binary value, the system tolerance level described above is not utilized.

Although this discussion is in terms of frequency, it should be recognized that the teachings of the invention are not limited to avoiding particular frequencies but may also select a processor frequency which avoids frequency bands associated with a particular radio frequency as well.

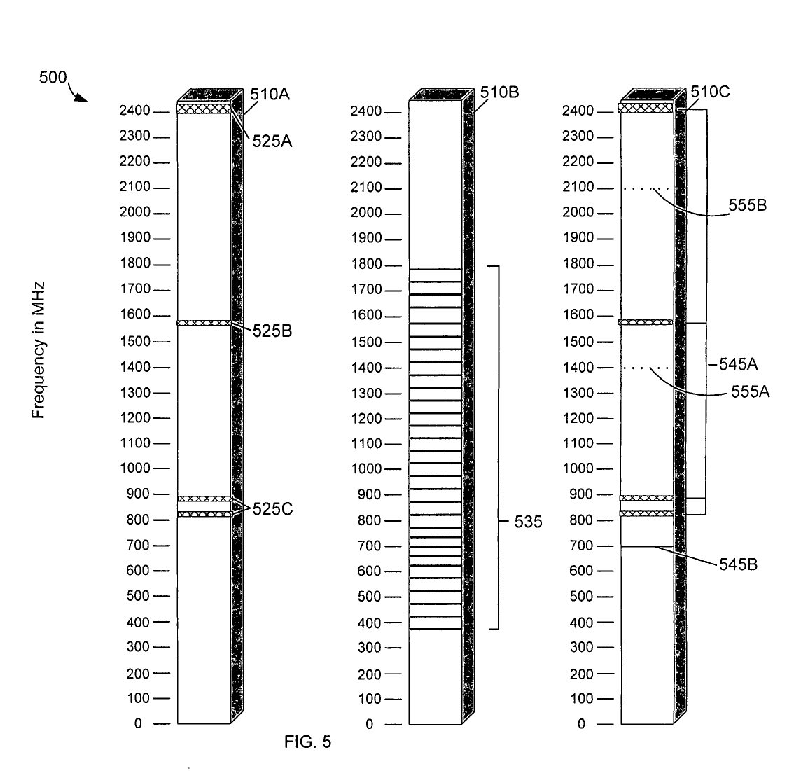

FIG. 5 shows a graphical illustration 500 of how to more flexibly allocate processor clock frequencies while reducing undue interference in accordance with the embodiment of the invention. The illustration 500 includes three frequency spectrums 510A-510C. Frequency spectrum 510A illustrates the bands of radio frequencies used by a wireless device modified according to the teachings of the invention at a first point in time. At this time, the wireless device such as wireless device 200 is communicating over the general use frequency band 525A, the GPS band 525B, and transmit and receive frequency bands 525C in the cellular band. The frequencies or frequency bands 525A-525C and their particular use are communicated in status information from the radio frequency controller 230.

Frequency spectrum 510B illustrates the potential processor frequencies 535 at which processor 265 or other peripheral device may operate. The potential processor frequencies 535 are specified in an allowance table, such as the allowance table 260. It should be noted that the range of potential frequencies may expand as the technology of frequency scaling processors progress. Furthermore, to save power consumption, processor 265 may employ voltage scaling which means operating the processor at lower voltage levels at the low frequency clock rate and higher voltage levels at the higher frequency clock rate. The more potential operating frequencies available, the more flexibility the processor clock control 255 has in selecting an operating frequency which meets processor throughput requirements while reducing power and reducing interference with used radio frequencies.

Frequency spectrum 510C illustrates the radio frequencies 545A used by the wireless device 200 and the selected frequency 545B for operating processor 265. First and second harmonic frequencies 555A and 555B of selected frequency 545B are also shown. Note that the selected frequency 700 MHz and its harmonics, 1400 MHz and 2100 MHz and so on, do not interfere with used radio frequencies 545A.

FIG. 6 is a spectral density graph 600 which illustrates slewing from an operating frequency of the processor of FIG. 2 at t₀ the selected operating frequency at t₄ in accordance with an embodiment of the invention. For the depicted example, the spectral density 610 of the current operating frequency for processor 265 is 1 GHz at time t₀ and the spectral density 650 of a selected frequency chosen by a wireless device modified according to the teachings of the invention is 400 MHz. To slew the operating frequency for processor 265, interim operating frequencies are chosen from an allowance table, such as allowance table 260, between the current operating frequency and the selected frequency to temporarily run the processor 265 at those interim operating frequencies. Slewing the operating frequency reduces power consumption and power transients caused by turning the processor 265 off when running at the current operating frequency and, then, turning the processor 265 on at the selected frequency in a step like function.

Rather then stepping between two operating frequencies, the operating frequency is slewed to selected interim frequencies which reduce interference of used radio frequencies. In the depicted example of FIG. 6, the operating frequency is slewed at time t₁, t₂, and t₃. It is possible that one or more slew positions may interfere with a used radio frequency. In order to reduce this interference, the processor clock controller 255 may calculate the number of slew positions to avoid interference with used radio frequencies by selecting frequencies in the allowance table 260 according to their corresponding interference factor. Alternatively, if the processor clock controller 255 determines that a slew position would interfere with a radio frequency, the processor clock controller 255 may reduce the interference by shortening the amount of time spent at an interfering slew position to achieve an acceptable bit error rate (BER).

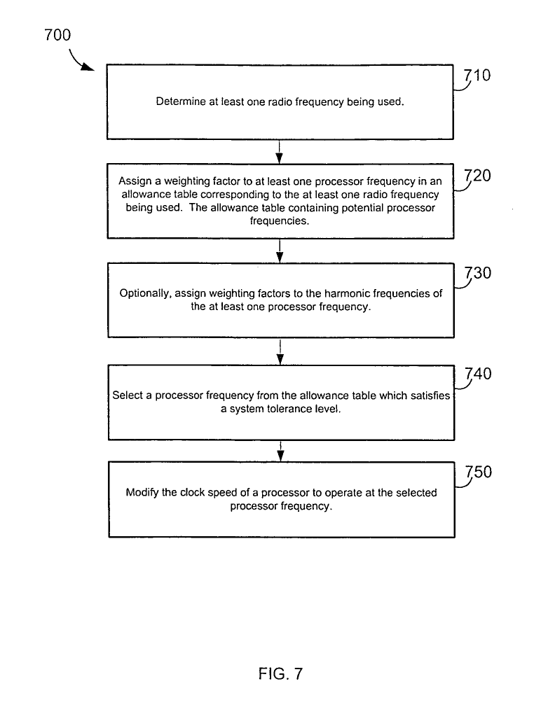

FIG. 7 is a flow chart illustrating a method 700 for reducing interference with used radio frequencies by varying the processor frequency in accordance with an embodiment of the invention. At step 710, the method 700 determines at least one radio frequency being used by a wireless device. In this step, the method may also determine one or more additional radio frequencies which might be used in the near future by the wireless device. At step 720, the method 700 assigns an interference factor to at least one processor frequency in an allowance table corresponding to the at least one radio frequency being used wherein the allowance table contains potential processor frequencies. Proceeding to optional step 730, the method 700 may assign interference factors to the harmonic frequencies of the at least one processor frequencies. Step 730 may identify even harmonics, odd harmonics or both depending on the at least one processor frequency.

At step 740, the method 700 selects a processor frequency from the allowance table which satisfies a system tolerance level, thus, ensuring that operating a processor or generating a clock signal at the selected frequency will not unacceptably interfere with radio frequencies in use or might be used in the near future. Step 740 may also integrate with conventional techniques of selecting operating speeds based on offered work load to a processor. To this end, step 740 may provide a list of frequencies extracted from the allowance table that have an interference factor of 0 to a conventional work load technique from which the conventional technique chooses to run a processor. Alternatively, step 740 may provide a list of frequencies that satisfy the system tolerance level to the conventional work load technique from which the conventional work load technique chooses to run a processor. By step 740 providing the list of frequencies that can be used in accordance with the teachings of the invention to a conventional technique, the conventional technique is enhanced to select a processor frequency which best matches the work load of the processor and, additionally, avoids undue interference with used radio frequencies.

While the invention is disclosed in the context of embodiments, it will be recognized that a wide variety of implementations may be employed by persons of ordinary skill in the art consistent with the above discussion and the claims which follow below.

We claim:

1. A method of controlling interference in a wireless device, the method comprising:
determining dynamically at least one radio frequency used in the wireless device;
assigning an interference factor to a potential processor frequency corresponding to at least one radio frequency used in the wireless device; and
selecting a first processor frequency other than the potential processor frequency assigned the interference factor to avoid interference with the at least one radio frequency.

2. The method of claim 1 wherein the potential processor frequency is disposed in an allowance table.

3. The method of claim 1 wherein the interference factor contains a binary value.

4. The method of claim 1 wherein the assigning step further comprises
assigning an interference factor of at least one harmonic frequency of the potential processor frequency.

5. The method of claim 1 wherein the at least one radio frequency used hops from one frequency to another frequency.

6. The method of claim 1 wherein the determining step further comprises
identifying the location of the wireless device with a global position system.

7. The method of claim 1 wherein the interference factor is a weighted value, the weighted value being greater than a threshold.

8. The method of claim 1 further comprising:
repeating the determining, assigning, and selecting steps to select a second processor frequency wherein the second processor frequency is not equal to the first processor frequency.

9. The method of claim 8 wherein the wireless device includes a frequency scaling processor, the method further comprising:
slewing the frequency scaling processor from operating at the first processor frequency to operate at the second processor frequency by choosing intermediate processor frequencies from a plurality of potential processor frequencies.

10. The method of claim 1 wherein the selected processor frequency controls the clock of a device wherein the device is a processor or a peripheral of the wireless device.

11. A wireless device comprising:
a radio frequency controller for determining at least one radio frequency used by the wireless device; and
a processor clock controller receiving the at least one used radio frequency, the processor clock controller selecting a first processor frequency from a plurality of potential processor frequencies, wherein at least one potential processor frequency in the plurality of potential processor frequencies is in the radio frequency band, wherein the first processor frequency is in the radio frequency band and does not interfere with the at least one used radio frequency.

12. The wireless device of claim 11 further comprising:
a memory containing an allowance table, wherein the allowance table contains the plurality of potential processor frequencies, wherein the processor clock controller assigns an interference factor to an entry in the allowance table corresponding to the at least one used radio frequency, wherein the processor clock controller selects the first processor frequency from the allowance table whose corresponding entry is unassigned.

13. The wireless device of claim 12 wherein the processor clock controller assigns an entry corresponding to at least one harmonic frequency of the corresponding to the at least one used radio frequency to avoid interference of harmonics of the at least one use radio frequency.

14. The wireless device of claim 11 wherein the at least one used radio frequency hops from one frequency to another frequency.

15. The wireless device of claim 11 wherein the radio frequency controller receives as input a location of the wireless device from a global positioning system (GPS) and determines the at least one used radio frequency from the location of the wireless device.

16. The wireless device of claim 11 further comprising:
a frequency scaling processor, wherein the processor clock controller selects a second processor frequency from the plurality of potential processor frequencies avoiding the at least one used radio frequency, the frequency scaling processor, in response to the selection of the second processor frequency, slewing its operating speed to the second processor frequency.

17. The wireless device of claim 11 wherein the first processor frequency controls a device wherein the device is a frequency scaling processor or a peripheral of the wireless device.

18. A computer readable medium whose contents cause a wireless device to determine at least one processor frequency in the radio frequency band which does not interfere with one or more used radio frequencies, the computer readable medium having a program to perform the steps of:
determining at least one radio frequency used in the wireless device;
assigning an interference factor to a potential processor frequency corresponding to at least one radio frequency used in the wireless device; and
selecting a first processor frequency other than the potential processor frequency assigned the interference factor to avoid interference with the at least one radio frequency.

19. The computer readable medium of claim 18 wherein the potential processor frequency is disposed in an allowance table.

20. The computer readable medium of claim 19 wherein the interference factor contains a binary value.
